(19) United States
(12) Patent Application Publication
(10) Pub. No.: US 2006/0255453 A1
(43) Pub. Date: Nov. 16, 2006

(54) Tightly engaged heat dissipating apparatus and method for manufacturing the same

(75) Inventor: Chung Wu, Taipei (TW)

Correspondence Address: HDSL, 4331 STEVENS BATTLE LANE, FAIRFAX, VA, 22033, US

(73) Assignee: Chaun-Choung Technology Corp.

(21) Appl. No.: 11/126,340

(22) Filed: May 11, 2005

(51) Int. Cl. H01L 23/34

(52) U.S. Cl. 257/720

(57) ABSTRACT

A method for manufacturing a tightly engaged heat dissipating apparatus includes the steps of providing a thermal-conductive base, forming a plurality of grooves on one surface of the base and forming a plurality of walls adjacent to the grooves, placing a plurality of fn plates of a heat dissipating unit into the grooves, and uniformly and vertically pressing the wall to distort the wall with lateral distortion. Therefore, the heat dissipating unit is clamped in the grooves with tight engagement.

### BACKGROUND OF THE INVENTION

1. Field of the Invention

The present invention relates to a tightly engaged heat dissipating apparatus and a method for manufacturing the same, especially to a heat dissipating apparatus manufactured by tightly engaging a heat dissipating unit with a thermal-conductive base together with a pressing force, whereby the yield and the heat dissipating effect can be enhanced.

2. Description of Related Art

FIGS. 1 to 3 show the structure and manufacturing process of a conventional heat dissipating apparatus for electronic devices. The conventional heat dissipating apparatus mainly comprises a flat base 1 made of highly thermal-conductive material, a plurality of grooves 11 defined on one surface of the base 1, a plurality of fin plate 12 each inserted into one of the grooves 11. As shown in those figures, pressing force is then exerted to both lateral sides of the base 1 to clamp tightly the plurality of fin plate 12 in the grooves 11, thus assembling the heat dissipating apparatus.

However, in above-mentioned heat dissipating apparatus with such manufacturing process, the base 1 is pressed on both lateral sides thereof. The center portion and the lateral portion of the base 1 may have uneven force. The fin plates 12 in the center grooves 11 away from the lateral sides of the base are not firmly clamped. The yield of the heat dissipating apparatus is influenced and the heat dissipating effect of the heat dissipating apparatus is degraded.

### SUMMARY OF THE INVENTION

The present invention provides a heat dissipating apparatus manufactured by tightly engaging a heat dissipating unit with a thermal-conductive base together with a pressing force, whereby the yield and the heat dissipating effect can be enhanced.

Accordingly, the present invention provides a method for manufacturing a tightly engaged heat dissipating apparatus, comprising the steps of providing a heat-conductive base, forming a plurality of grooves on one surface of the base and forming a plurality of walls adjacent to the grooves, placing a plurality of heat dissipating units into the grooves, and uniformly and vertically pressing the wall to distort the wall with lateral distortion, whereby the heat dissipating units are clamped in the grooves.

Moreover, the present inventions also provides a tightly engaged heat dissipating apparatus, which comprises a thermal-conductive base comprising a plurality of grooves on one surface of the base and a plurality of walls adjacent to the grooves and deformable for providing clamping effect for the grooves, and a plurality of heat dissipating units firmly clamped into the grooves.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a step for manufacturing a conventional heat dissipating apparatus for electronic devices.

FIG. 2 shows another step for manufacturing a conventional heat dissipating apparatus for electronic devices.

FIG. 3 shows still another step for manufacturing a conventional heat dissipating apparatus for electronic devices.

FIG. 4 shows the first step of manufacturing a tightly engaged heat dissipating apparatus according to a preferred embodiment of the present invention.

FIG. 5 shows the second step of manufacturing a tightly engaged heat dissipating apparatus according to a preferred embodiment of the present invention.

FIG. 6 shows the third step of manufacturing a tightly engaged heat dissipating apparatus according to a preferred embodiment of the present invention.

FIG. 7 shows the fourth step of manufacturing a tightly engaged heat dissipating apparatus according to a preferred embodiment of the present invention.

FIG. 8 is a partially enlarged view of the dashed circle in FIG. 7.

FIG. 9 is a sectional view of the tightly engaged heat dissipating apparatus according to a preferred embodiment of the present invention.

FIG. 10 shows a step of manufacturing a tightly engaged heat dissipating apparatus according to another preferred embodiment of the present invention.

FIG. 11 shows another step of manufacturing a tightly engaged heat dissipating apparatus according to another preferred embodiment of the present invention.

FIG. 12 is a sectional view of the tightly engaged heat dissipating apparatus according to another preferred embodiment of the present invention.

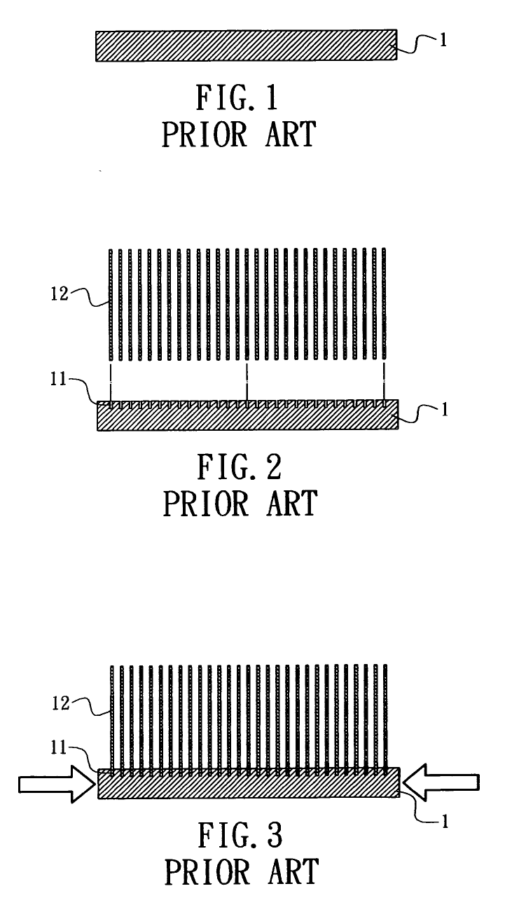

### DETAILED DESCRIPTION OF THE INVENTION

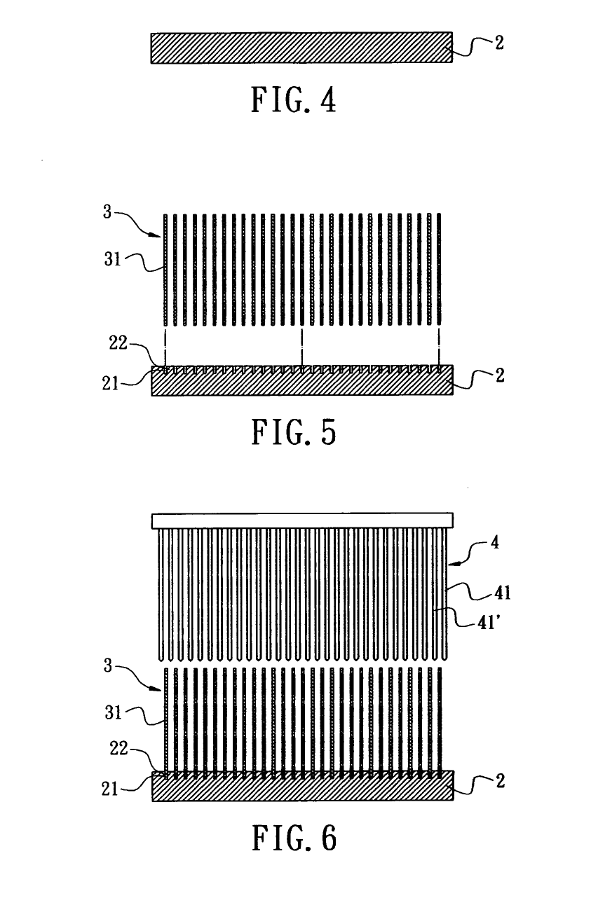

FIGS. 4 to 9 show the processing steps of the method for manufacturing a tightly engaged heat dissipating apparatus by pressing according to a preferred embodiment of the present invention.

Step 1: Providing a thermal-conductive base 2, which is a flat base made of highly thermal-conductive material, as shown in FIG. 4.

Step 2: Performing assembling step by forming a plurality of grooves 21 on one surface of the base 2 and a plurality of walls 22 adjacent to the grooves 21, and providing a plurality of heat dissipating units 3 inserted into the grooves 21 by one end thereof, as shown in FIG. 5.

Step 3: Providing a processing tool 4, which comprises a plurality of pressing units 41 arranged on one face thereof and separated to each other. Each of the pressing units 41 is corresponding to a surface of the wall 22 and the adjacent pressing units 41, 41′ have same pitch therebetween to provide a gap for receiving one fin plate 31 of the heat dissipating units 3, as shown in FIG. 6.

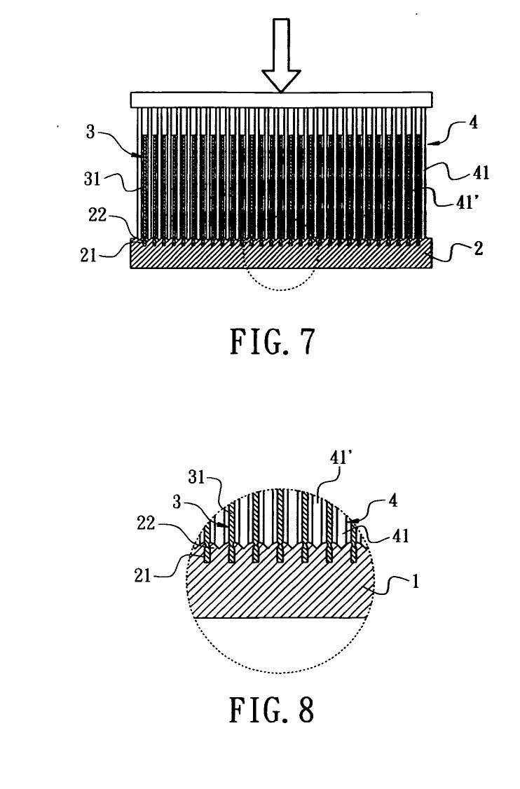

Step 4: Performing pressing step, the processing tool 4 is pressed against the thermal conductive base 2 with high pressure, as shown FIG. 7. Therefore, the end of each pressing unit 41 will press against the wall 22 and the wall 22 has expansion distortion to change the shape of an opening of the groove 21. An inward clamping force is resulted to clamp one end of the heat dissipating unit 3, as shown in FIG. 8.

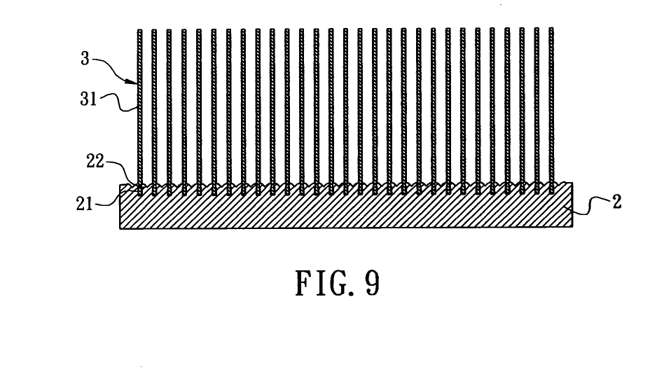

Step 5: Removing the processing tool 4 and achieving a tightly engaged heat dissipating apparatus, as shown in FIG. 9.

According to one preferred embodiment of the present invention, the heat dissipating unit 3 is composed of a plurality of fin plates 31 and forms the tightly engaged heat dissipating apparatus with the base 2.

According the method for manufacturing the tightly engaged heat dissipating apparatus, a simple processing tool 4 is employed to vertically press the wall 22 of the base 2. The wall 22 is subjected to uniform pressing force and expands toward the grooves 21 on both sides thereof. Therefore, one end of the fin plate 31 of the heat dissipating unit 3 can be firmly clamped by the grooves 21. The manufacturing method is simple and effective. The heat dissipating apparatus can be manufactured with lower cost and simpler steps.

The tightly engaged heat dissipating apparatus manufactured by above-mentioned method, as shown in FIG. 9, comprises a thermal-conductive base 2, a plurality of grooves 21 on one surface of the thermal-conductive base 2, a plurality of walls each placed between two adjacent grooves 21, and a plurality of fin plate 31 inserted into the grooves 21.

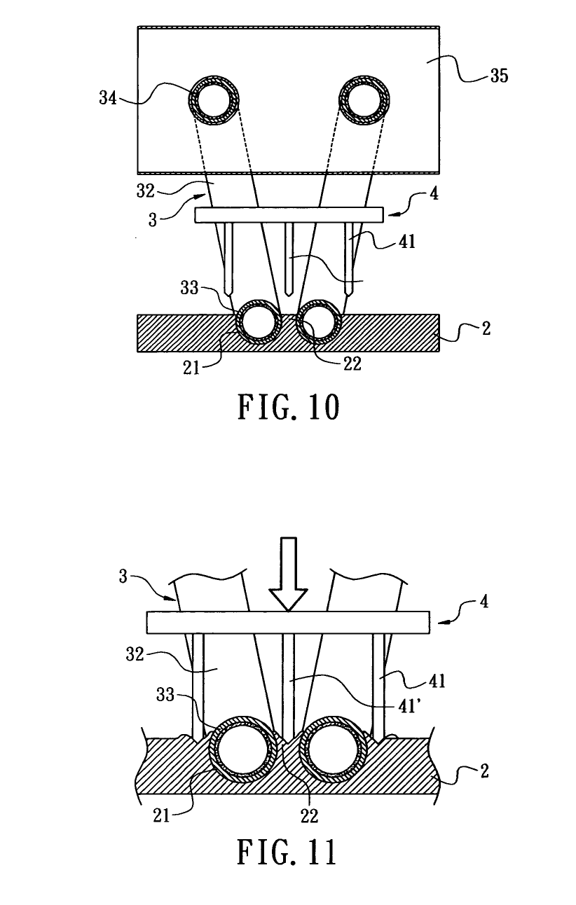

According to a preferred embodiment of the present invention, the heat dissipating unit 3 comprises a plurality of fin plates 31 as shown in FIG. 9, or comprises at least one heat pipe assembly 32 as shown in FIG. 10, or the combination thereof.

FIGS. 10 and 11 show the steps for the manufacturing method of the present invention, which is applied to tightly engaged heat pipe assembly. Some steps for this preferred embodiment are similar to those shown in FIGS. 4 to 8, namely, forming a plurality of grooves 21 on one surface of a base 2 and forming a plurality of walls 22 each placed between two adjacent grooves 21.

Afterward, the heat dissipating unit 3 with a plurality of heat pipe assembly 32 are assembled, wherein a heat-receiving end 33 of each heat pipe assembly 32 is inserted into one groove 21. A processing tool 4 with a plurality of pressing units 41 is used to press the wall 22 to distort the wall, as shown in FIG. 10. The wall 22 between adjacent grooves 21 is distorted to firmly clamp the heat-receiving end 33 of each heat pipe assembly 32.

The heat dissipating apparatus manufactured by above-mentioned method, as shown in FIG. 10, comprises a thermal-conductive base 2, a plurality of grooves 21 on one surface of the thermal-conductive base 2, a plurality of walls 22 each placed between two adjacent grooves 21, and at least one heat pipe assembly 32 assembled to the grooves 21 by tightly pressing. The cooling end of the heat pipe assembly 32 can be further assembled with a plurality of fin plates 35.

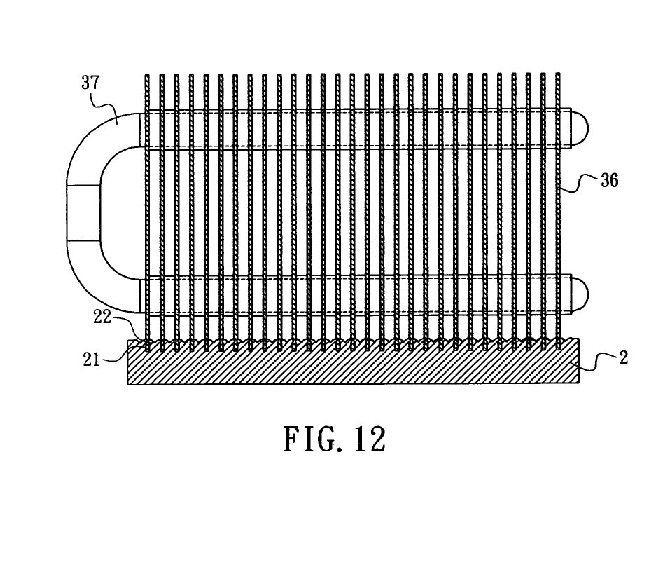

FIG. 12 shows another heat dissipating apparatus manufactured according to still another preferred embodiment of the present invention. The dissipating apparatus comprises a thermal-conductive base 2, a plurality of grooves 21 on one surface of the thermal-conductive base 2, a plurality of walls 22 each placed between two adjacent grooves 21, a plurality of fin plates 36 firmly clamped in the grooves 21 and a heat pipe 37 passing through the plurality of fin plates 36.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A method for manufacturing a tightly engaged heat dissipating apparatus, comprising the steps of:
providing a thermal-conductive base;
forming a plurality of grooves on one surface of the base and forming a plurality of walls adjacent to the grooves;
placing a heat dissipating unit into the grooves; and
uniformly and vertically pressing the wall to distort the wall with lateral distortion, whereby the heat dissipating unit is clamped in the grooves.

2. The method for manufacturing a tightly engaged heat dissipating apparatus as in claim 1, further comprising:
providing a processing tool to vertically press the walls to distort the wall with lateral distortion.

3. The method for manufacturing a tightly engaged heat dissipating apparatus as in claim 2, wherein the processing tool comprises a plurality of separated pressing units and one end of each pressing unit is pressed against the wall with high and uniform pressure.

4. The method for manufacturing a tightly engaged heat dissipating apparatus as in claim 3, wherein the processing tool comprises a plurality of separated pressing units with equal separation to press the wall for each of fin plates in the heat dissipating unit.

5. The method for manufacturing a tightly engaged heat dissipating apparatus as in claim 1, wherein the heat dissipating unit comprises a plurality of fn plates, or at least one heat pipe assembly or the combination thereof.

6. A heat dissipating apparatus made by a method for tightly engaging the heat dissipating apparatus, comprising
a thermal-conductive base comprising a plurality of grooves on one surface of the base and a plurality of walls adjacent to the grooves and deformable for providing clamping effect for the grooves; and
a plurality of fin plates firmly clamped into the grooves.

7. A heat dissipating apparatus comprising:
a thermal-conductive base comprising a plurality of grooves on one surface of the base and a plurality of walls adjacent to the grooves and deformable for providing clamping effect for the grooves; and
at least one heat pipe assembly having a heat receiving end tightly engaged into the groove and a cooling end.

8. The heat dissipating apparatus as in claim 7, wherein the cooling end is further assembled with a heat dissipating unit with a plurality of fin plates.

9. A heat dissipating apparatus comprising:
a thermal-conductive base comprising a plurality of grooves on one surface of the base and a plurality of walls adjacent to the grooves and deformable for providing clamping effect for the grooves;
a plurality of fin plates firmly clamped into the grooves; and
at least one heat pipe assembled to the plurality of fin plates.
